(19) United States
(12) Patent Application Publication
(10) Pub. No.: US 2025/0038484 A1
(43) Pub. Date: Jan. 30, 2025

(54) NANOWIRES, NANOWIRE OPTICAL DEVICE AND NANOWIRE LIGHT EMITTING DEVICE

(71) Applicant: Nippon Telegraph and Telephone Corporation, Tokyo (JP)

(72) Inventors: Masato Takiguchi, Tokyo (JP); Masaya Notomi, Tokyo (JP); Taiki Yoda, Tokyo (JP); Hisashi Sumikura, Tokyo (JP); Akihiko Shinya, Tokyo (JP)

(21) Appl. No.: 18/715,326

(22) PCT Filed: Feb. 10, 2022
(86) PCT No.: PCT/JP2022/005361

§ 371 Date: May 31, 2024

(51) Int. Cl. H01S 5/34

(52) U.S. Cl. CPC H01S 5/341

(57) ABSTRACT

A nanowire of the present invention is a columnar semiconductor, and includes a hollow part in a central axis direction of the columnar semiconductor, in which a central axis of the columnar semiconductor and a central axis of the hollow part substantially coincide with each other to generate a vector beam. In the nanowire, a nanowire diameter may be two times or more and four times or less of an upper limit value of the nanowire diameter in which light exists in a single mode. Further, a horizontal cross section of the columnar semiconductor may be circular or polygonal.

### CROSS-REFERENCE TO RELATED APPLICATIONS

This application is a national phase entry of PCT Application No. PCT/JP2022/005361, filed on Feb. 10, 2022, which application is hereby incorporated herein by reference.

### TECHNICAL FIELD

The present invention relates to a nanowire, a nanowire optical element and a nanowire light-emitting device for generating a vector beam.

### BACKGROUND

In recent years, a device for generating a vector beam has been extensively studied and developed. The vector beam has a donut-like electric field distribution, and is expected to be applied to capture nano-materials, laser processing, super-resolution microscopes, and the like.

Normally, the vector beam is generated by reflecting, transmitting, or the like, light from a light source by a hologram, a crystal having a refractive index distribution, a plurality of wavelength plates, or the like. Since the vector beam generator is constituted by combining bulk-sized optical elements, it becomes large-sized. In order to reduce the size and power consumption of the generator, it is important to directly generate a vector beam from the light source and to miniaturize the light source itself.

Also, vector beam generation utilizing nano-structures such as meta-surfaces is also performed. In this case, although it is possible to reduce the size of the generator as compared with a generator having a configuration in which bulk optical elements are combined, the structure is complicated.

On the other hand, a small laser using nanowires has been realized (NPL 1). A semiconductor nanowire is an ultrafine semiconductor nanomaterial having a diameter of several 10 nm to several μm and a length of several μm. Further, the structure is simple, a large amount of the semiconductor can be grown on the substrate at a time, and a Group III-V semiconductor or the like can be directly formed on the silicon substrate. Therefore, it is desired to generate a vector beam by a laser using a nanowire.

### CITATION LIST

### Non Patent Literature

NPL 1 M. Notomi, M. Takiguchi, S. Sergent, G. Zhang, and H. Sumikura, “Nanowire photonics toward wide wavelength range and subwavelength confinement” Opt. Mater. Express, 10, 2560 (2020).
Https://www.osapublishing.org/ome/fulltext.cfm?uri=ome-10-10-2560&id=439732

### SUMMARY

### Technical Problem

However, when the nanowire laser is used for generating the vector beam, selection of modes existing in the nanowire becomes an issue. Usually, in a columnar structure having a circular or polygonal cross section such as a nanowire, an electric field mode similar to that of an optical fiber is formed. Therefore, in the nanowires, a Gaussian beam exists instead of a vector beam in the base mode, and a vector beam having a donut-like electric field distribution exists in a higher-order mode. As a result, the vector beam cannot be extracted from the nanowire with high efficiency.

Therefore, in order to extract the vector beam from the nanowire with high efficiency, it is necessary that the Gaussian beam do not exist in a base mode of the nanowire and the vector beam exists.

### Solution to Problem

In order to solve the above problem, a nanowire according to embodiments of the present invention is a columnar semiconductor, and includes a hollow part in a central axis direction of the columnar semiconductor, in which a central axis of the columnar semiconductor and a central axis of the hollow part substantially coincide with each other to generate a vector beam.

### Advantageous Effects of Embodiments of Invention

According to embodiments of the present invention, it is possible to provide a nanowire, a nanowire optical element, and a nanowire light-emitting device that generate a vector beam with high efficiency.

### BRIEF DESCRIPTION OF THE DRAWINGS

FIG. 1A is a schematic external view of a nanowire according to a first embodiment of the present invention.

FIG. 1B is a schematic external view of an example of the nanowire according to the first embodiment of the present invention.

FIG. 2A is a schematic horizontal cross-sectional view of the nanowire according to the first embodiment of the present invention.

FIG. 2B is a light intensity distribution diagram in a horizontal cross section of the nanowire according to the first embodiment of the present invention.

FIG. 3 is a diagram showing a dispersion relationship in nanowires having no hollow part.

FIG. 4A is a light intensity distribution diagram in the horizontal cross section of the nanowire having no hollow part.

FIG. 4B is a light intensity distribution diagram in the horizontal cross section of the nanowire having no hollow part.

FIG. 5 is a diagram showing a dispersion relationship in the nanowire according to the first embodiment of the present invention.

FIG. 6A is a light intensity distribution diagram in the horizontal cross section of the nanowire according to the first embodiment of the present invention.

FIG. 6B is a light intensity distribution diagram in the horizontal cross section of the nanowire according to the first embodiment of the present invention.

FIG. 6C is a light intensity distribution diagram in the horizontal cross section of the nanowire according to the first embodiment of the present invention.

FIG. 7A is a light intensity distribution diagram in the horizontal cross section of the nanowire according to the first embodiment of the present invention.

FIG. 7B is a light intensity distribution diagram in a vertical cross section of the nanowire according to the first embodiment of the present invention.

FIG. 8 is a schematic external view of a nanowire according to a second embodiment of the present invention.

FIG. 9 is a diagram showing the dispersion relationship in the nanowire according to the second embodiment of the present invention.

FIG. 10A is a light intensity distribution diagram in a horizontal cross section of the nanowire according to the second embodiment of the present invention.

FIG. 10B is a light intensity distribution diagram in the horizontal cross section of the nanowire according to the second embodiment of the present invention.

FIG. 11A is a light intensity distribution diagram in the horizontal cross section of the nanowire according to the second embodiment of the present invention.

FIG. 11B is a light intensity distribution diagram in the vertical cross section of the nanowire according to the second embodiment of the present invention.

FIG. 12A is a schematic horizontal cross-sectional view showing an example of the nanowire according to the second embodiment of the present invention.

FIG. 12B is a schematic vertical cross-sectional view showing an example of the nanowire according to the second embodiment of the present invention.

FIG. 13A is a schematic horizontal cross-sectional view showing an example of the nanowire according to the second embodiment of the present invention.

FIG. 13B is a schematic vertical sectional view showing an example of the nanowire according to the second embodiment of the present invention.

FIG. 14A is a schematic horizontal cross-sectional view showing an example of a nanowire according to a modified example of the embodiment of the present invention.

FIG. 14B is a schematic vertical sectional view showing an example of a nanowire according to a modified example of the embodiment of the present invention.

FIG. 15A is a schematic horizontal cross-sectional view showing an example of a nanowire according to a modified example of the embodiment of the present invention.

FIG. 15B is a schematic vertical sectional view showing an example of a nanowire according to a modified example of the embodiment of the present invention.

FIG. 16 is a configuration diagram of a nanowire light-emitting device according to a third embodiment of the present invention.

FIG. 17A is a light intensity distribution diagram for explaining the operation of the nanowire light-emitting device according to the third embodiment of the present invention.

FIG. 17B is a light intensity distribution diagram for explaining the operation of the nanowire light-emitting device according to the third embodiment of the present invention.

FIG. 18A is a light intensity distribution diagram for explaining the operation of the nanowire light-emitting device according to the third embodiment of the present invention.

FIG. 18B is a light intensity distribution diagram for explaining the operation of the nanowire light-emitting device according to the third embodiment of the present invention.

FIG. 19A is a light intensity distribution diagram for explaining the operation of the nanowire light-emitting device according to the third embodiment of the present invention.

FIG. 19B is a light intensity distribution diagram for explaining the operation of the nanowire light-emitting device according to the third embodiment of the present invention.

### DETAILED DESCRIPTION OF ILLUSTRATIVE EMBODIMENTS

### First Embodiment

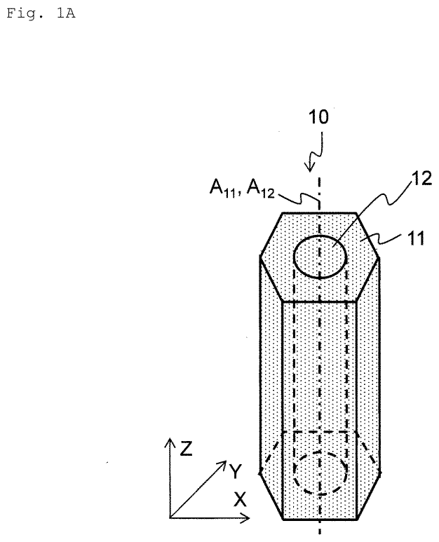

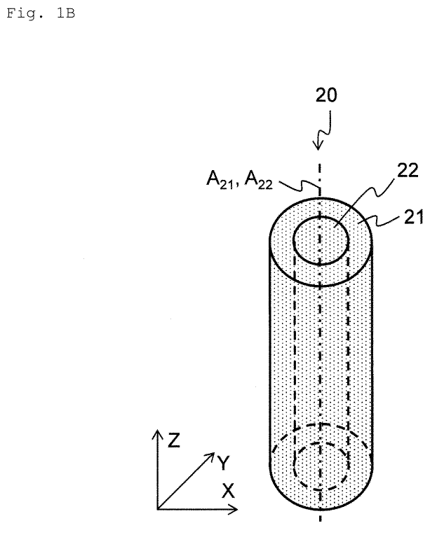

A nanowire according to a first embodiment of the present invention will be described with reference to FIGS. 1A to 7B.

### Configuration of Nanowire

A nanowire 10 according to the present embodiment includes a nanowire having a hollow part 12, as shown in FIG. 1A. Specifically, a body 11 of the nanowire 10 is columnar GaN having a regular hexagonal shape in a cross section (hereinafter referred to as “horizontal cross section”) on a horizontal plane (XY plane in the drawing). A length r₁ from a center to an apex of the regular hexagon of the horizontal cross section is 200 nm. The length in a central axis direction (Z direction in the drawing) may be 200 nm or more. Here, the horizontal cross-sectional shape of the regular hexagon is because GaN is hexagonal.

The hollow part 12 has a circular horizontal cross section, is disposed substantially at the center in the central axis direction (Z direction) of the body 11 of the nanowire 10, and penetrates the body 11 of the nanowire 10. In other words, a central axis A₁₁ of the body 11 of the nanowire 10 and a central axis A₁₂ of the hollow part substantially coincide with each other. A radius r₂ of the horizontal cross section of the hollow part 12 is 108 nm. Here, the “approximate center” includes an absolute center, and includes a range of processing errors. Similarly, “substantially match” includes complete match and includes a range of processing errors.

The nanowire 20 may be made up of columnar GaN having a circular horizontal cross-sectional shape, as shown in FIG. 1B.

Here, although an example in which the body of the nanowire is made up of GaN is shown, the present invention is not limited to this example, and other semiconductors such as GaAs, InP, and SiGe may be used. Further, a layer structure made of a plurality of materials such as a multi-quantum well (MQW) may be provided.

Further, the horizontal cross-sectional shape of the nanowire 10 is not limited to a regular hexagonal shape and a circular shape, but may be a polygonal shape. Here, the circular and polygonal shapes are preferably regular circles or regular polygons having symmetry. The length from the center to the apex of the polygon in the horizontal cross section of the nanowire 10 or the radius in the circle (hereinafter referred to as the nanowire diameter) r₁ is preferably 150 nm or more and 300 nm or less.

The horizontal cross-sectional shape of the hollow part 12 is not limited to a circular shape, but may be a regular hexagon or a polygon. Here, the circular and polygonal shapes are preferably regular circles or regular polygons having symmetry. In a horizontal cross section of the hollow part 12, the length from a center to an apex in a polygon or a radius in a circle (hereinafter referred to as “hollow diameter”) r₂ may be such an extent that light can be confined in the nanowire 10, for example, a lower limit may be several nm, and an upper limit may be such an extent that the thickness of the side face of the body 11 of the nanowire 10 becomes 10 nm.

The nanowire 10 according to the present embodiment is manufactured, for example, as follows.

First, after a GaN buffer layer is grown on a sapphire substrate, hexagonal GaN is formed as a regular hexagonal columnar nanowire crystal (body).
Next, a hollow part (hole) 12 is formed in a nanowire crystal (body), by dry-etching or a sublimation method (a top-down selective-area sublimation method) using a pattern by electron beam drawing.

Finally, the nanowire 10 having the hollow part is separated from the GaN buffer layer.

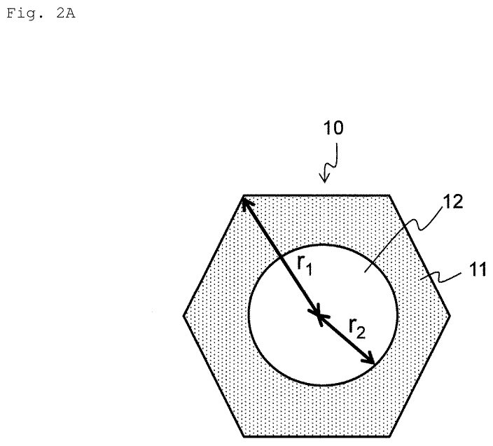

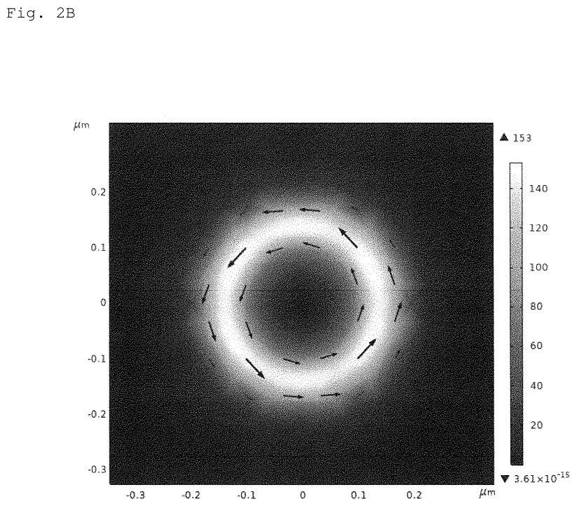

FIGS. 2A and 2B show examples of simulation results of the electric field distribution of the nanowire 10 according to the present embodiment. In the simulation, a nanowire made up of GaN is used, and the refractive index of GaN is set to 2.022. As shown in FIG. 2A, the horizontal cross-sectional shape of the nanowire body 11 is a regular hexagon, and the nanowire diameter r1 is set to 200 nm. The horizontal cross-sectional shape of the hollow part 12 is a regular circle, and the hollow diameter r₂ is set to 0.54 times (108 nm) the nanowire diameter r₁.

The simulation was performed by a two-dimensional finite element method simulation (product name: COMSOL Multiphysics, manufacturer: COMSOL Inc.).

FIG. 2B shows the light intensity (electric field) distribution in the nanowire 10. Arrows in the drawing show a direction of the electric field at a specific phase.

In the nanowire 10, light (electric field) is distributed in a donut shape. This shows that the nanowire 10 can generate a vector beam having a donut-like electric field distribution as a base mode.

Next, the operation of the nanowire 10 according to the present embodiment will be described.

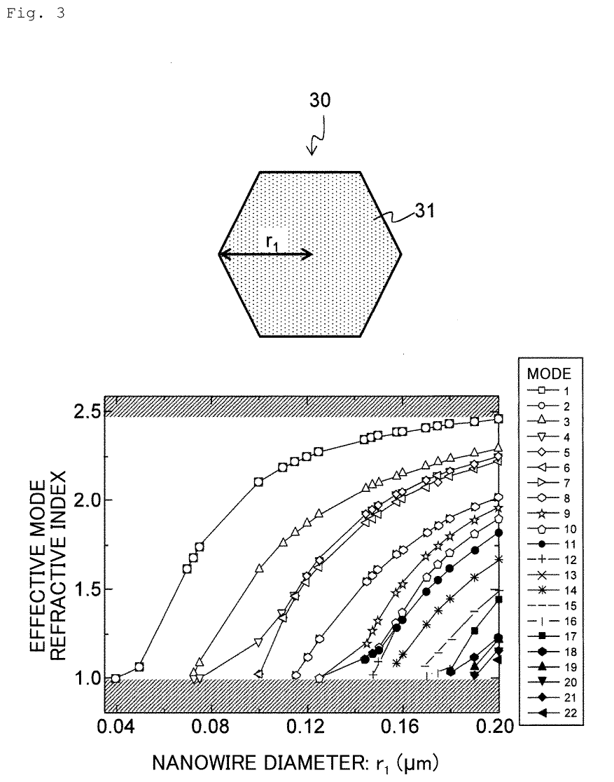

First, the optical mode distribution of the nanowire 30 having no hollow part will be described. FIG. 3 shows a simulation result of the dispersion relation of the optical mode of the nanowire 30 having no hollow part. An abscissa represents a nanowire diameter r₁, and an ordinate represents an effective mode refractive index. The nanowire material is GaN, and the wavelength is set near 400 nm. In the drawing, the horizontal cross section of the nanowire 30 used in simulation is shown in an insertion diagram.

As the nanowire diameter r₁ increases, the number of optical modes existing in the nanowire 30 increases, and when the nanowire diameter r₁ is 0.2 μm, there are 22 modes. The effective mode refractive index of each mode increases, as the nanowire diameter r₁ increases.

Mode 1 and mode 2 exist degenerately over the whole range of the nanowire diameter (0.04 μm to 0.20 μm). Here, since mode 1 and mode 2 are degenerated, they are plotted in an overlapping manner in the drawing.

In the whole range of the nanowire diameter, the degenerated mode 1 and mode 2 exhibit the highest effective mode refractive index and are therefore base modes, and single mode exists up to nanowire diameter r1 of 0.075 μm.

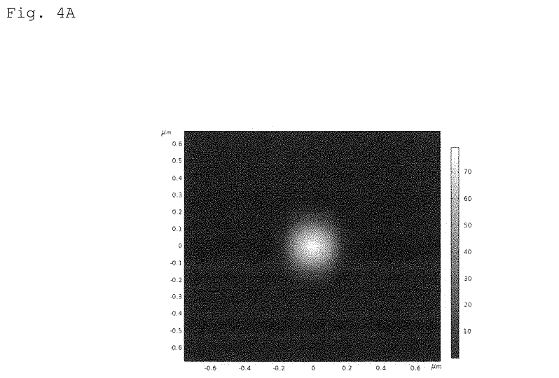

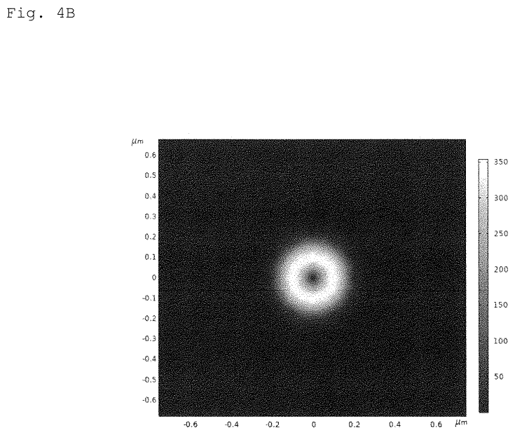

Each of FIGS. 4A and 4B shows the light intensity distribution of mode 1 and mode 3 in a horizontal cross section of the nanowire 30 with nanowire diameter r1 of 0.20 μm. Here, the light intensity distribution in mode 2 is the same as that in mode 1.

In mode 1, the light intensity is high at the center of the nanowire 30, as shown in FIG. 4A. Therefore, mode 1 is not a vector beam but a Gaussian beam. In this way, the degenerated mode 1 and mode 2, which are the base modes, are Gaussian beams.

On the other hand, mode 3 shows a donut-like mode distribution as shown in FIG. 4B, and is a vector beam of a so-called azimuth polarization mode.

Here, mode 1 and mode 2 which are degenerated in the whole range of the nanowire diameter indicate the distribution of Gaussian beams. On the other hand, mode 3 shows a donut-like mode distribution (vector beam).

Thus, the nanowire 30 having no hollow part has a mode distribution similar to that of a general optical fiber, and the vector beam is always present in a higher order mode rather than a base mode, and the vector beam cannot be efficiently extracted.

Next, the light intensity distribution of the nanowire 10 having a hollow part according to the present embodiment will be described.

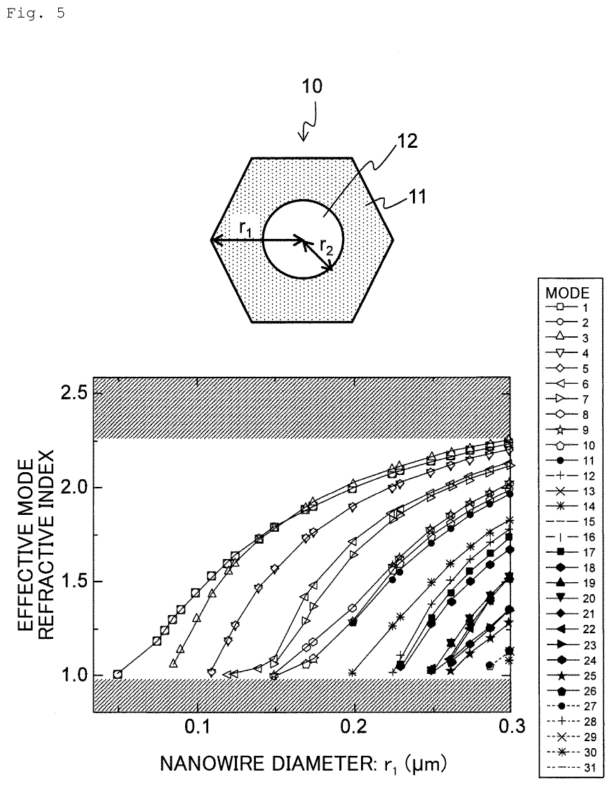

FIG. 5 shows simulation results of mode dispersion relationship of the nanowire 10. The abscissa indicates a nanowire diameter r1, and the ordinate indicates an effective mode refractive index.

In the drawing, the horizontal cross-sectional shape of the nanowire 10 used in simulation is shown in the insertion diagram. A diameter (hollow diameter) r2 of the hollow part 12 disposed at the center of the nanowire 10 is set to 0.54 times the nanowire r1.

As the nanowire diameter r1 increases, the number of optical modes existing in the nanowire 10 increases, and when the nanowire diameter r1 is 0.3 μm, there are 31 modes. The effective mode refractive index of each mode increases, as the nanowire diameter r1 increases.

Mode 1 and mode 2 exist degenerately over the whole range of the nanowire diameter (0.02 μm to 0.30 μm), and a single mode exists up to a nanowire diameter r1 of 0.075 μm (75 nm). Here, since mode 1 and mode 2 are degenerated, they are plotted in an overlapping manner in the drawing.

In addition, in the range in which the nanowire diameter r1 is up to about 0.15 μm (150 nm), degenerated mode 1 and mode 2 exhibit the highest effective mode refractive index, and when the nanowire diameter r1 is about 0.15 μm (150 nm) or more, mode 3 shows the highest effective mode refractive index. In this way, when the nanowire diameter r1 is approximately 0.15 μm (150 nm), the base mode changes (inverts) from the degenerated modes 1 and 2 to mode 3.

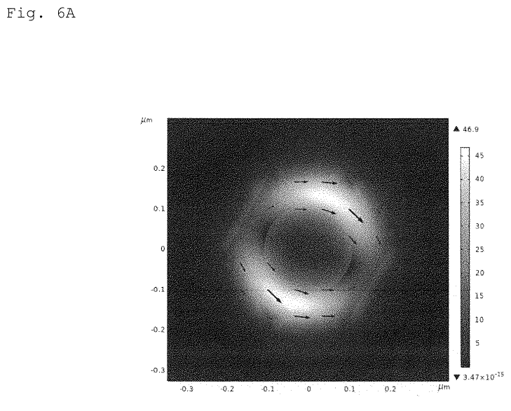

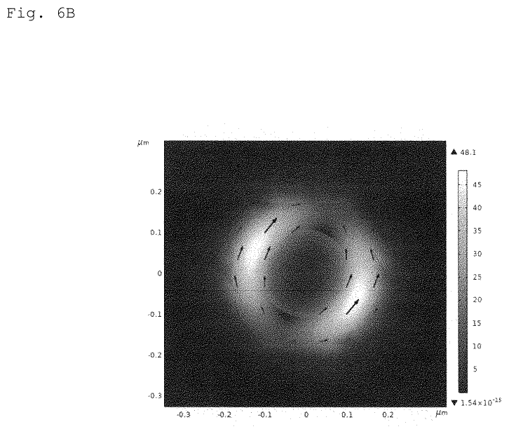

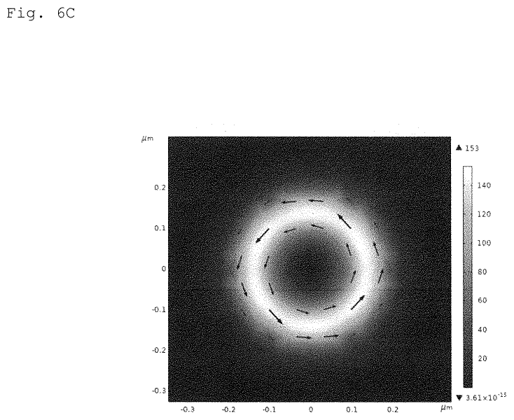

FIGS. 6A, 6B, and 6C each show the light intensity distributions of mode 1, mode 2, and mode 3 in the horizontal cross section of the nanowire 10 with nanowire diameter r1 of 0.20 μm. The arrows in the drawing indicate the direction of the electric field at a specific phase.

As shown in FIGS. 6A and 6B, in modes 1 and 2, a portion having a high light intensity is divided into two portions, and the electric field distribution is divided. At this time, the light is not distributed in the center portion, and the light does not exist in the region of air of the hollow part 12 of the nanowire 10.

On the other hand, as shown in FIG. 6C, in mode 3, the light exhibits a donut-like distribution, and is a vector beam of a so-called azimuth polarization mode.

Here, mode 1 and mode 2 show split electric field distributions in the whole range of the nanowire diameter, and mode 3 shows donut-like mode distribution (vector beam).

As a result, in the base mode of the nanowire 10, the nanowire diameter r₁ is about 0.15 μm (150 nm) or more, and becomes mode 3, that is, the vector beam mode.

As described above, in modes 1 and 2, since the hollow part is disposed in the nanowire having a small diameter, the electric field distribution is divided and light cannot exist in the air region of the hollow part, as the effective refractive index is lowered because the oozing of the light into the air is further increased, the effective refractive index of mode 3 becomes a value larger than the effective refractive index of modes 1 and 2, and it is considered that the inversion of the base mode occurs.

In this way, the inversion of the base mode occurs in the nanowire diameter region of about twice (150 nm) the upper limit (75 nm) of the nanowire diameter r1 in which the light exists in the single mode. Thus, the nanowire diameter is preferably two times or more the upper limit of the nanowire diameter in which light exists in the single mode. Further, it is desirable that the light be four times or less of the upper limit of the nanowire diameter in which the light exists in the single mode.

Thus, according to the nanowire 10, a vector beam having a diameter equal to or larger than a predetermined nanowire diameter exists in the base mode, and the vector beam can be efficiently extracted.

Next, the resonance characteristic of mode 3, which is the base mode of the nanowire 10, will be described.

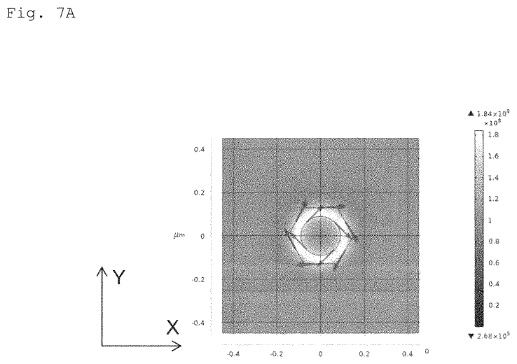

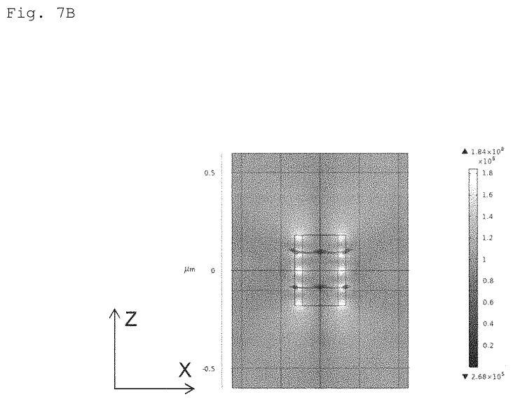

FIGS. 7A and 7B are three-dimensional simulation results of the electric field (light intensity) distribution of mode 3 in the nanowire 10, and are a horizontal cross-sectional view and a vertical cross-sectional view, respectively. Here, “vertical cross section” refers to a cross section on a vertical plane (XZ plane in the drawing). The arrows in the drawing indicate the direction of the electric field at a specific phase.

The nanowire diameter r1 is set to 200 nm, and the hollow diameter r2 is set to 108 nm.

As shown in FIG. 7A, the electric field distribution of mode 3 has the shape of a vector beam. Also, as shown in FIG. 7B, the electric field (light) is confined in the vertical direction (Z direction). In this way, in the nanowire 10, a resonator structure by end face reflection is formed in the base mode of the vector beam.

A Q-value of the resonator of the nanowire 10 is about 1500, and has light confinement necessary for laser oscillation.

### Effect

The nanowire 10 according to the present embodiment has a hollow core structure having a hollow part (hole) at the center. According to the nanowire according to the present embodiment, since there is no mode in which light is confined in the hollow part, concentration of light at the center can be suppressed. Thus, the base mode of the nanowire can be converted into a vector beam under a predetermined condition of the nanowire diameter r1 and the hollow diameter r2, and the vector beam can be generated with high efficiency.

Here, in the optical fiber, the hollow core optical fiber has a hollow part, like the nanowire according to the present embodiment. However, in the hollow core optical fiber, the electric field is confined and propagated in the hollow part, and therefore, the operation and effect are different from those of the nanowire according to the present embodiment.

In the nanowire according to the present embodiment, light can be made incident from the outside to generate a vector beam. As will be described later, a p-type layer and an n-type layer are formed on the nanowire, and a vector beam can be emitted by injecting a current from the outside. Further, by forming the resonator structure, laser oscillation can be performed by the vector beam.

### Second Embodiment

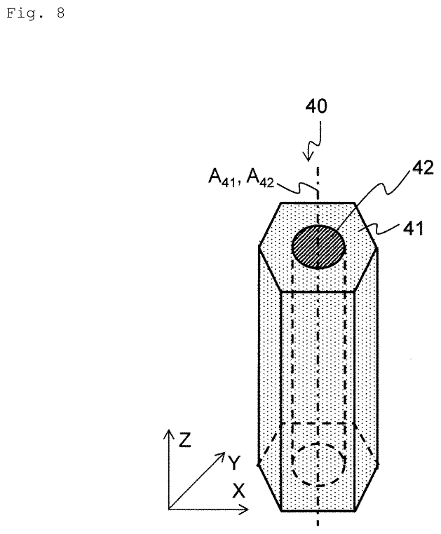

A nanowire according to a second embodiment of the present invention will be described with reference to FIGS. 8 to 13B.

### Nanowire Configuration

In a nanowire 40 according to the present embodiment, as shown in FIG. 8, a portion corresponding to the hollow part of the nanowire according to the first embodiment is filled with a metal 42, and the portion filled with the metal passes through a nanowire body 41. Here, gold is used as the metal 42, but other metals such as aluminum and silver may be used. The other components are the same as in the first embodiment.

The nanowire 40 according to the present embodiment is manufactured by, for

example, processing a hollow part in a nanowire crystal (body), and then inserting a cylindrical metal 42 into the hollow part and fixing the metal 42 in the hollow part, as in the first embodiment.

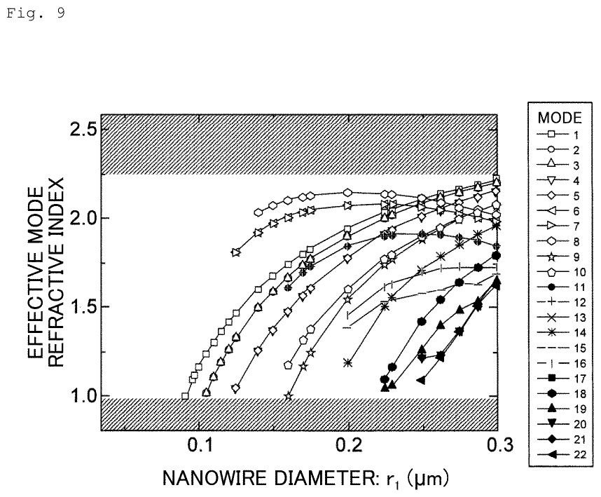

FIG. 9 shows a simulation result of the dispersion relationship of modes of the nanowires 40. The abscissa shows the nanowire diameter r1, and the ordinate shows the effective mode refractive index. The diameter r2 of the metal 42 placed at the center of the nanowire 40 was set to 0.54 times the nanowire diameter r1.

As the nanowire diameter r1 increases, the number of optical modes existing in the nanowire 40 increases, and when the nanowire diameter r1 is 0.3 μm, 22 modes exist. Here, since mode 2 and mode 3 are degenerated, they are plotted in an overlapping manner in the drawing.

In addition, only mode 1 exists in a region in which the nanowire diameter r1 is up to about 0.11 μm (110 nm), and in this region mode 1 is a single mode, which is the base mode.

Further, when the nanowire diameter r1 is 0.125 to 0.14 μm, modes 6 and 7 are degenerated and are the base mode, and when the nanowire diameter r1 is 0.14 to 0.25 μm, mode 8 is the base mode.

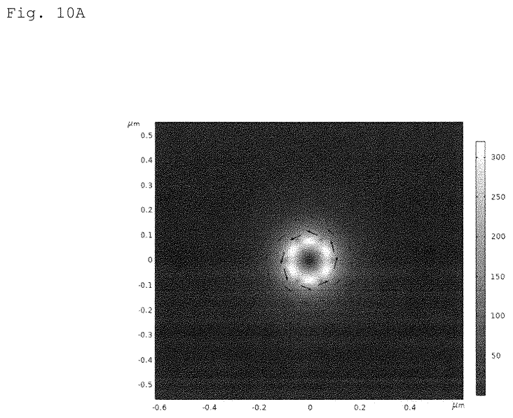

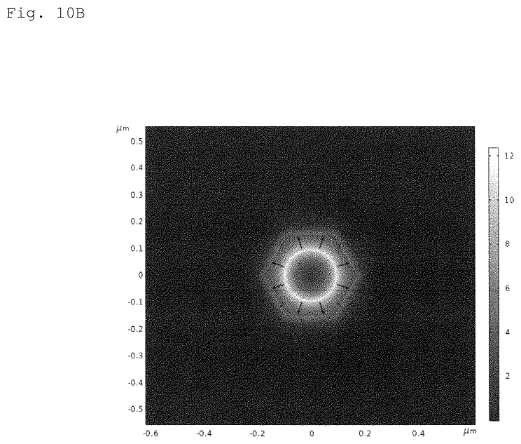

FIGS. 10A and 10B each show the light intensity distribution of mode 1 in a horizontal cross section of the nanowire 40 with the nanowire diameter r1 of 0.10 μm, and the light intensity distribution of mode 8 in a horizontal cross section of the nanowire 40 with a nanowire diameter r1 of 0.15 μm. Here, the arrows in the drawing indicate the direction of the electric field at a specific phase.

As shown in FIG. 10A, mode 1 shows a donut-like distribution, and is a vector beam of mode of azimuth polarization. In this way, in mode 1, since light cannot exist at the center portion in which the metal 42 is disposed, a vector beam exists as a base mode instead of a Gaussian beam.

In this way, the nanowire 40 has a nanowire diameter r1 of about 0.09 μm (90 nm) to 0.11 μm (110 nm), and can generate vector beam of a single mode.

As shown in FIG. 10B, mode 8 shows a donut-like distribution in which the electric field is distributed in the radial direction, and is a vector beam of a radial polarization mode.

In this way, when the nanowire diameter r1 is 0.14 to 0.25 μm, a plasmomic mode vector beam in which the electric field is concentrated on the metal 42 of the center portion can be generated in the base mode.

Here, mode 1 indicates a mode of an azimuth polarization vector beam, and mode 8 indicates a mode of a vector beam of radial polarization in the whole range of the nanowire diameter.

Next, the resonance characteristic of mode 1, which is the base mode of the nanowire 40, will be described.

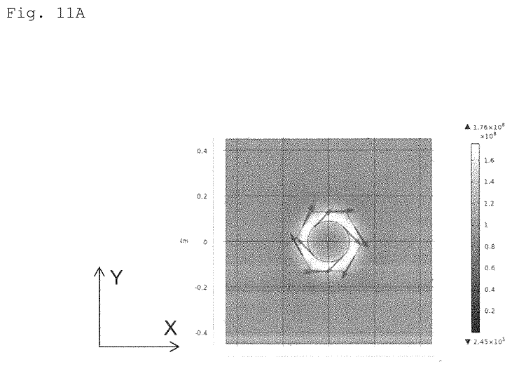

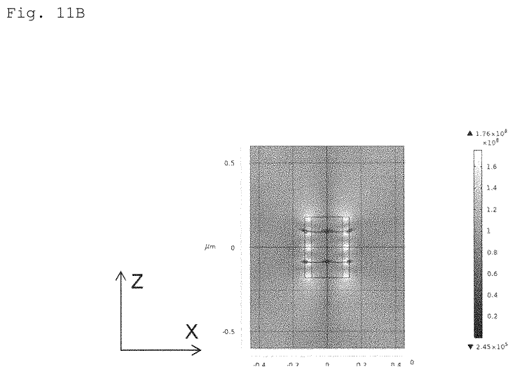

FIGS. 11A and 11B are three-dimensional simulation results of the electric field (light intensity) distribution of mode 1 in the nanowire 40, and are a horizontal cross-sectional view and a vertical cross-sectional view, respectively. The arrows in the drawing indicate the direction of the electric field at a specific phase. Here, the nanowire diameter r1 is 100 nm, and the hollow diameter r2 is 54 nm.

As shown in FIG. 11A, the electric field distribution of mode 1 has the shape of a vector beam. As shown in FIG. 11B, the electric field (light) is confined in the vertical direction (Z direction). In this way, in the nanowire 40, a resonator structure by end face reflection is formed in the base mode of the vector beam.

The Q-value of the resonator of the nanowire 40 is about 60, and has light confinement necessary for laser oscillation. The Q value can be improved by disposing an insulating film (for example, SiO2) between the nanowire and the metal.

In addition, a resonator structure is similarly formed for mode 8, which is the base mode and has a nanowire diameter r1 of 0.14 to 0.25 μm.

In the present embodiment, although an example in which the metal is filled in the entire hollow part of the nanowire is shown, the present invention is not limited thereto, and the metal may be disposed in a part of the hollow part.

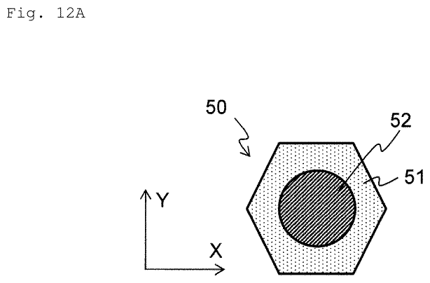

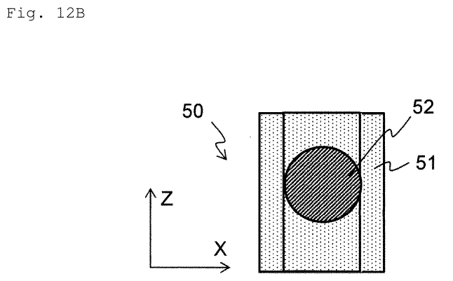

For example, metal microspheres 52 may be disposed in the hollow part, as in the nanowire 50 shown in FIGS. 12A and 12B. For example, a commercially available metal ball having an outer diameter of about several 10 to 100 nm, which is made of gold, may be used as the metal microspheres 52. In this configuration, the distribution of vector beams is formed around the metal microspheres 52.

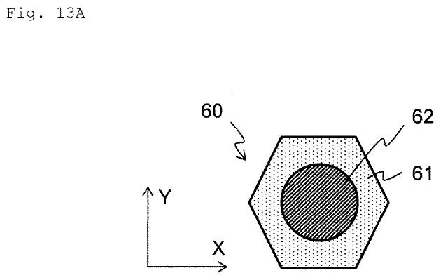

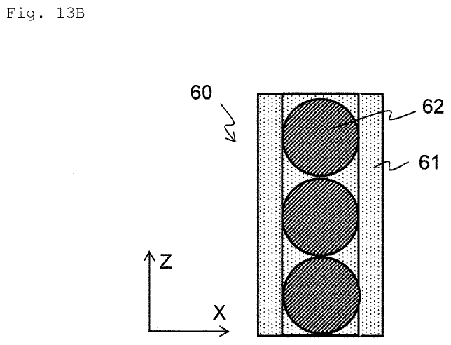

A plurality of metal microspheres 62 may be disposed in the hollow part as in the nanowire 60 shown in FIGS. 13A and 13B. In this configuration, the electric field distribution can be periodically formed in a central axis direction (Z direction), and the same effect as the nano-sized antenna can be obtained.

### Effect

In the nanowire according to the present embodiment, since there is no mode in which light is confined in the metal of the center, as in the first embodiment, the concentration of light at the center can be suppressed. Thus, the base mode of the nanowire can be turned into a vector beam under a predetermined condition, and the vector beam can be generated with high efficiency.

Further, according to the nanowire according to the present embodiment, since the vector beam of the base mode can be generated in a single mode, it is suitable for signal transmission in an optical fiber or a waveguide in optical communication or the like.

Therefore, the same effects as in the first embodiment can be achieved.

### Modified Example of Nanowire

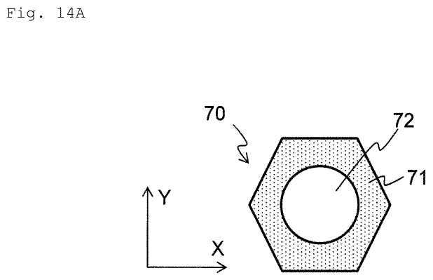

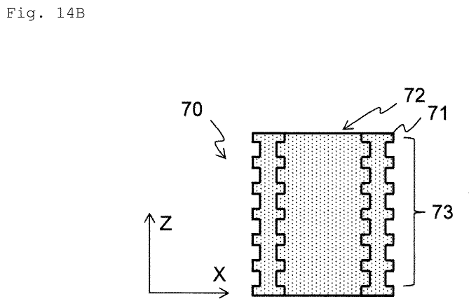

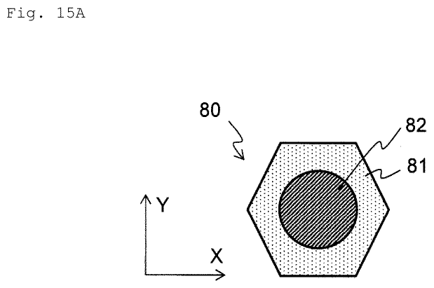

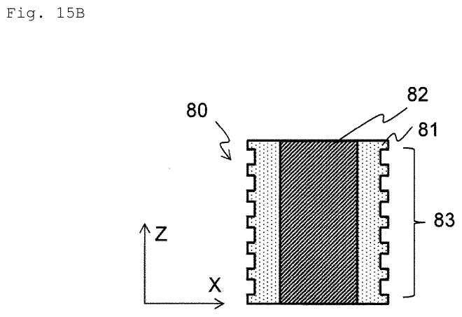

A nanowire 70 according to the modified example of the embodiment of the present invention may have a grating structure 73 that is periodic in the central axis direction (Z direction) in an outer peripheral region of the nanowire (body 71) having a hollow part 72, as shown in FIGS. 14A and 14B. Further, as in a nanowire 80 shown in FIGS. 15A and 15B, a grating structure 83 which is periodic in the central axis direction (Z direction) may be provided in an outer peripheral region of the nanowire (main body 81) having a metal 82 at the center part.

The periodic structures (gratings) 73 and 83 of the nanowire can be formed by etching the nanowire periodically including materials having different etching rates in the central axis direction (Z direction), for example, under predetermined etching conditions.

According to the nanowire according to the present modified example, light confinement can be realized as a resonator, and the Q value can be improved.

### Third Embodiment

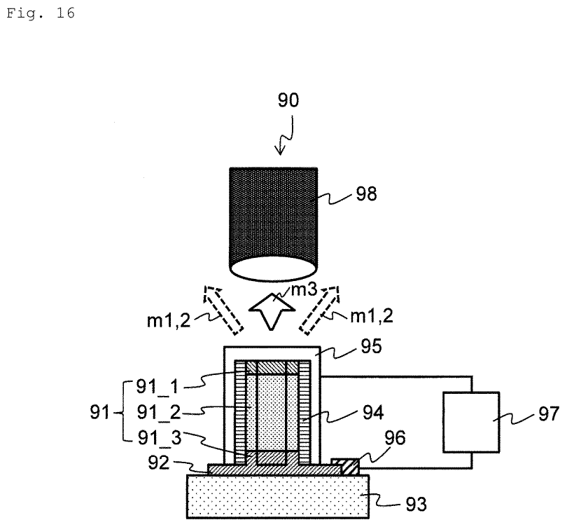

A nanowire light-emitting device according to a third embodiment of the present invention will be described with reference to FIGS. 16 to 19B.

### Configuration of Nanowire Light-Emitting Device

A nanowire light-emitting device 90 according to the present embodiment is configured using a nanowire laser. As shown in FIG. 16, the nanowire light-emitting device 90 includes a nanowire 91 on a sapphire substrate 93 via a nanowire base end portion 92.

The nanowire 91 is made up of GaN of a pin structure, includes a p-type GaN 91_1 at one end portion (for example, an upper surface side) and an n-type GaN 91_3 at the other end portion (for example, a base end portion side), and includes an i-type GaN 91_2 between the p-type GaN 91_1 and the n-type GaN 91_3. The other configurations of the nanowire 91 are the same as those of the first embodiment.

The nanowire base end portion 92 is made of n-type GaN.

An insulating layer 94 is provided on a side surface of the nanowire 91.

A transparent electrode 95 (p-type electrode) is disposed to cover an end face of one (for example, p-type GaN 91_1), and an n-type electrode 96 is provided at a nanowire base end portion 92 electrically connected to the end face of the other (for example, n-type GaN 91_3).

A current is injected from an external power source 97 connected to each of the transparent electrode (p-type electrode) 95 and the n-type electrode 96, and laser beams (dotted arrows m1, 2 and a solid arrow m3 in the drawing) are emitted from one end portion (for example, the upper surface side).

The nanowire laser includes at least the nanowire 91, the p-type electrode 95, and the n-type electrode 96.

Further, an NA lens 98 is disposed in the vicinity of the end face on the emission side of the nanowire 91 so that the laser beam is made incident. By the NA lens 98, only the light of the base mode (solid line arrow m3 in the drawing) can be collected and extracted (output) from the laser light (dotted line arrows m1, 2 and solid line arrow m3 in the drawing) of the nanowire 91 having a multi-mode. Here, an NA optical element such as a high NA fiber may be used instead of the NA lens.

### Method for Manufacturing Nanowire Laser

An example of a method for manufacturing the nanowire laser used in the embodiment will be described below.

First, an n-type GaN buffer layer is grown as the nanowire base end portion 92 on the sapphire substrate 93, and then GaN having a hexagonal pin structure is formed as a regular hexagonal columnar nanowire crystal (body).

Next, a hollow part (hole) is formed by dry-etching using a pattern by electron beam drawing in a nanowire crystal (body) to manufacture the nanowire 91 having the hollow part.

Next, the insulating layer 94 is formed on the side surface of the nanowire, using an atomic layer deposition (ALD) device.

Next, the insulating layer adhered to the upper surface of the nanowire at the time of ALD is removed by dry-etching to expose the upper surface of the nanowire 91.

Next, the transparent electrode 95 of ITO or the like is formed, using sputtering or the like to cover the upper surface of the nanowire 91.

Finally, the n-type electrode 96 is formed at the nanowire base end portion 92.

### Operation of Nanowire Light-Emitting Device

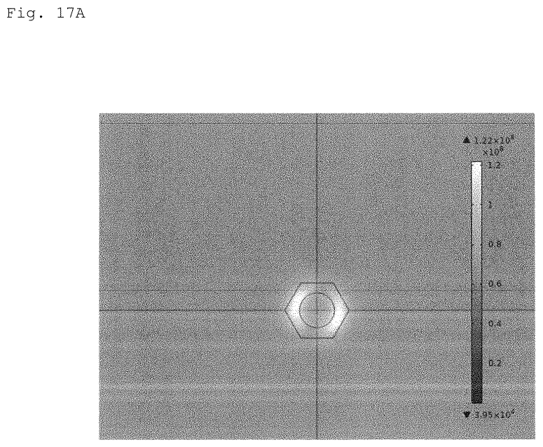

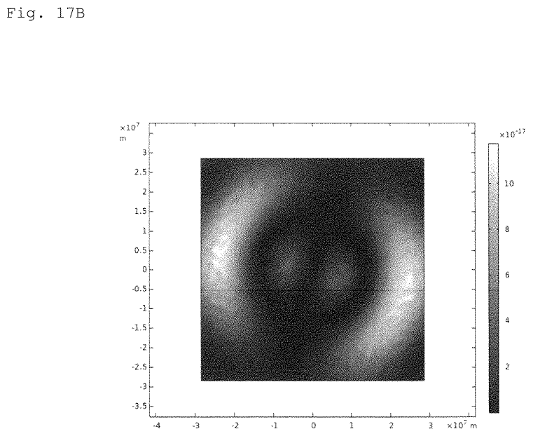

The operation of the nanowire light-emitting device 90 according to the present embodiment will be explained with reference to FIGS. 17A to 19B.

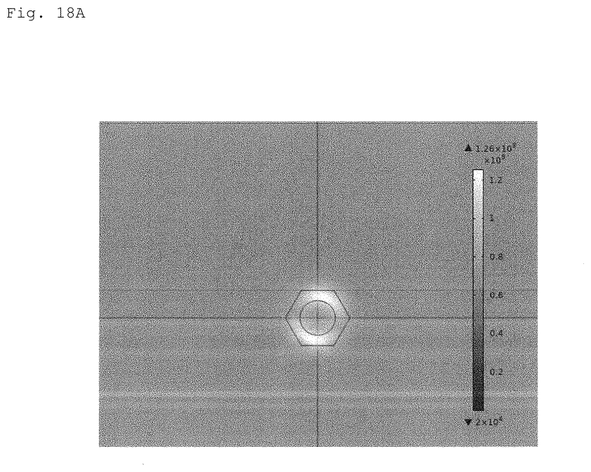

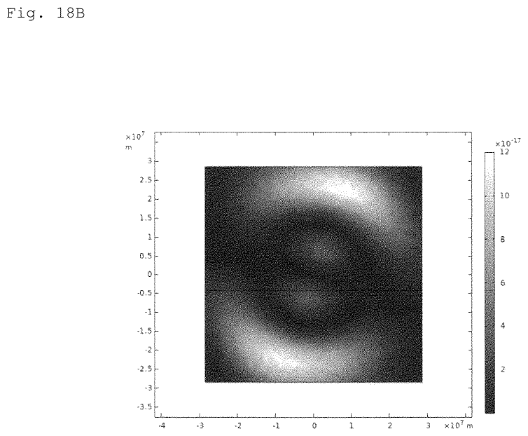

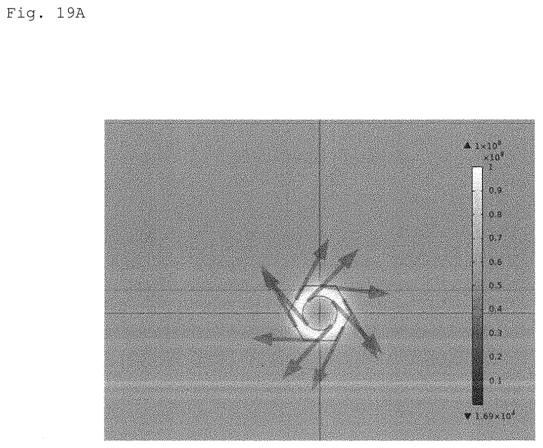

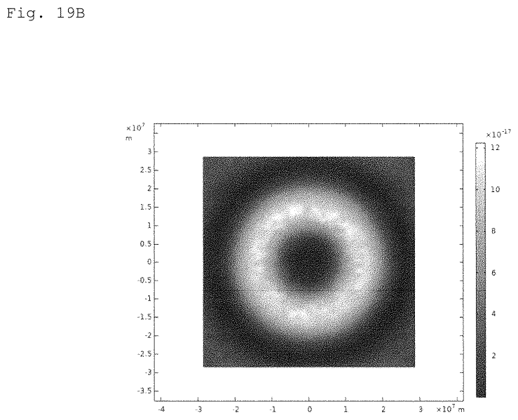

FIGS. 17A and 17B show near-field images and far-field images of mode 1 in the nanowire 10 (corresponding to the nanowire 91 according to the present embodiment) according to the first embodiment. Similarly, FIGS. 18A to 19B show near-field and far-field images of modes 2, 3 in the nanowire 10, respectively. In order to compare each of the near-field image and the far-field image, the near-field image and far-field image of each mode are shown on the same scale. The arrows in the drawing indicate the direction of the electric field at a specific phase.

In the near-field image, modes 1 to 3 have a diameter of approximately the same size, modes 1 and 2 show the tendency of division of the electric field distribution, and mode 3 shows the donut-like electric field distribution (FIGS. 17A, 18A, and 19A).

On the other hand, in the far-field image, the electric fields of modes 1 and 2 are clearly divided (FIGS. 17B and 18B), and mode 3 shows a donut-like electric field distribution (FIG. 19B). In the far-field image, the electric fields of modes 1 and 2 are distributed wider than that of mode 3. That is, a spread angle of the electric field (light) in modes 1 and 2 in the emission direction is larger than that in mode 3.

Therefore, if an NA lens 98 disposed at a predetermined distance (for example, a distance at which the far-field image is acquired) from the emission end of the nanowire laser with respect to the emission light is used, light of mode 1 and 2 (dotted line arrows m1 and 2 in FIG. 16) is excluded, only the light of mode 3 (solid line arrow m3 in FIG. 16) can be condensed and extracted (output), and only the light of the vector mode (mode 3) can be extracted (output).

In this way, only the light (mode) of the vector beam can be extracted (output), by using a lens having an appropriate NA for the light emission of the nanowire including the light of the multi-mode.

In particular, as shown in the first embodiment, when a vector beam of a base mode is generated with a predetermined nanowire diameter, if a high-order mode is also induced, the high-order mode is excluded by an appropriate NA lens, and only the vector beam of the base mode can be extracted (output).

### Effect

According to the nanowire light-emitting device according to the present embodiment, a vector beam of a base mode can be efficiently extracted.

Further, according to the nanowire light-emitting device according to the present embodiment, an ultra-small vector beam generator can be realized.

Although the configuration of the nanowire according to the first embodiment is used in the present embodiment, the configuration of the nanowire according to the second embodiment and modified example may be used.

In the embodiments of the present invention, although an example in which the hollow part or the metal filled in the hollow part penetrates the nanowire body has been shown, the present invention is not limited thereto, the metal may not penetrate the nanowire body, the metal may be thick enough to generate a vector beam in the base mode, and the metal may be disposed in the hollow part such that the length is about the length of the wavelength in consideration of the effective refractive index.

In the embodiment of the present invention, an example in which a laser is used as an optical element of a nanowire is shown, other optical elements such as a light-emitting diode (LED) and a semiconductor optical amplifier (SOA) may be used.

In the embodiments of the present invention, although examples of the configurations, dimensions, materials, and the like of each component are shown in the configurations, manufacturing methods, and the like of the nanowire, the nanowire optical element, and nanowire light-emitting device, the present invention is not limited thereto. Any material may be used as long as it exhibits the functions and effects of the nanowire, the nanowire optical element, and the nanowire light-emitting device.

### INDUSTRIAL APPLICABILITY

Embodiments of the present invention can be applied to capture nano-materials, laser processing, super-resolution microscopes, and the like.

### REFERENCE SIGNS LIST

10 Nanowire
11 Nanowire body
12 Hollow part

1-8. (canceled)

9. A nanowire, comprising:
a columnar semiconductor; and
a hollow part along a central axis direction of the columnar semiconductor,
wherein a central axis of the columnar semiconductor and a central axis of the hollow part substantially coincide with each other to generate a vector beam.

10. The nanowire according to claim 9,
wherein a nanowire diameter is two times or more and four times or less an upper limit value of a nanowire diameter in which light exists in a single mode.

11. The nanowire according to claim 10, wherein at least a part of the hollow part includes a metal.

12. The nanowire according to claim 9, wherein a horizontal cross section of the columnar semiconductor is circular.

13. The nanowire according to claim 9, wherein a horizontal cross section of the columnar semiconductor is polygonal.

14. The nanowire according to claim 9, wherein at least a part of the hollow part includes a metal.

15. The nanowire according to claim 14,
wherein the metal is a metal microsphere.

16. The nanowire according to claim 9,
wherein a periodic structure is provided along a side surface of the nanowire.

17. A nanowire optical element comprising:
a nanowire, comprising:
a columnar semiconductor; and
a hollow part along a central axis direction of the columnar semiconductor; and
an electrode electrically connected to a first end portion and a second end portion of the nanowire,
wherein a central axis of the columnar semiconductor and a central axis of the hollow part substantially coincide with each other to generate a vector beam, and
wherein the first end portion is a p-type semiconductor, and second other end portion is an n-type semiconductor.

18. The nanowire optical element according to claim 17, wherein a nanowire diameter is two times or more and four times or less an upper limit value of a nanowire diameter in which light exists in a single mode.

19. The nanowire optical element according to claim 17, wherein a horizontal cross section of the columnar semiconductor is circular.

20. The nanowire optical element according to claim 17, wherein a horizontal cross section of the columnar semiconductor is polygonal.

21. The nanowire optical element according to claim 17, wherein at least a part of the hollow part includes a metal.

22. The nanowire optical element according to claim 21, wherein the metal is a metal microsphere.

23. The nanowire optical element according to claim 17, wherein a periodic structure is provided along a side surface of the nanowire.

24. A nanowire light-emitting device comprising:
a nanowire optical element comprising:
a nanowire, comprising:
a columnar semiconductor; and
a hollow part along a central axis direction of the columnar semiconductor;
an electrode electrically connected to a first end portion and a second end portion of the nanowire; and
an NA optical element adjacent to a first end face of the nanowire optical element,
wherein a central axis of the columnar semiconductor and a central axis of the hollow part substantially coincide with each other to generate a vector beam,
wherein the first end portion is a p-type semiconductor, and second other end portion is an n-type semiconductor, and
wherein the NA optical element is configured to condense only light in a mode of a vector beam among light emitted from the first end face of the nanowire optical element.
